(19) United States
(12) Patent Application Publication
(10) Pub. No.: US 2021/0079264 A1
(43) Pub. Date: Mar. 18, 2021

(54) POLISHING COMPOSITION, METHOD FOR PRODUCING POLISHING COMPOSITION, POLISHING METHOD, AND METHOD FOR PRODUCING SEMICONDUCTOR SUBSTRATE

(71) Applicant: FUJIMI INCORPORATED, Aichi (JP)

(72) Inventors: Ryota MAE, Aichi (JP); Shogo Onishi, Aichi (JP)

(73) Assignee: FUJIMI INCORPORATED, Aichi (JP)

(21) Appl. No.: 17/008,872

(22) Filed: Sep. 1, 2020

(30) Foreign Application Priority Data
Sep. 13, 2019 (JP) 2019-167314

(51) Int. Cl. C09G 1/02; H01L 21/321

(52) U.S. Cl. CPC C09G 1/02; H01L 21/3212

(57) ABSTRACT

A polishing composition according to the present invention contains colloidal silica and a quaternary ammonium compound represented by Formula (1), wherein a pH is less than 4.0, and a zeta potential of the colloidal silica is −60 mV or higher and −35 mV or lower.

### CROSS-REFERENCE TO RELATED APPLICATION

The entire disclosure of Japanese Patent Application No. 2019-167314 filed on Sep. 13, 2019 is incorporated herein by reference in its entirety.

### BACKGROUND

### 1. Technical Field

The present invention relates to a polishing composition, a method for producing a polishing composition, a polishing method, and a method for producing a semiconductor substrate.

### 2. Description of Related Arts

In recent years, along with the trend for forming multilayer wiring on the surface of semiconductor substrates, a so-called chemical mechanical polishing (CMP) technology for physically polishing and flattening and a semiconductor substrate has been utilized at the time of device production. The CMP is a method of flattening the surface of an object to be polished (object being polished) such as a semiconductor substrate, using a polishing composition (slurry) including abrasive grains such as silica, alumina, ceria, or the like, an anti-corrosion agent, a surfactant, and the like, and examples of the object to be polished (object being polished) include wirings, plugs, and the like formed from silicon, polysilicon, silicon oxide (SiO₂), carbon-containing silicon oxide (SiOC), silicon nitride (SiN), metals, and the like.

For example, in JP 2008-091569 A (corresponding to KR 2008-30479 A and TW 200817498 A), a polishing composition for polishing an insulating film having a low relative dielectric constant, such as SiOC, the polishing composition including colloidal silica particles, a benzotriazole compound, and a secondary or tertiary amino alcohol and a pH of which is in the range of 7 to 10, is disclosed. It is considered that according to this technology, the generation of scratches in an insulating film of SiOC or the like can be suppressed.

### SUMMARY

However, it was found that in the technology described in JP 2008-091569 A (corresponding to KR 2008-30479 A and TW 200817498 A), there is a problem that the increase in the polishing speed is still insufficient.

Therefore, it is an object of the present invention to provide a polishing composition that can polish SiOC at a high polishing speed.

The inventors of the present invention repeatedly have conducted a thorough investigation in order to solve the above-described problems. As a result, the inventors have found that the above-described problems are solved by a polishing composition, containing colloidal silica and a quaternary ammonium compound represented by the following Formula (1):

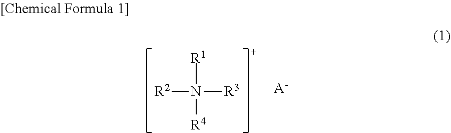

wherein one or two groups among R¹ to R⁴ each independently represent a first group, which is an alkyl group having 3 or more and 20 or less carbon atoms, an alkenyl group having 3 or more and 20 or less carbon atoms, or an aryl group having 6 or more and 20 or less carbon atoms; the remaining three or two groups other than the first group among R¹ to R⁴ each independently represent a second group, which is an alkyl group having 1 or 2 carbon atoms or an alkenyl group having 2 carbon atoms; and A⁻ represents a monovalent anion,

wherein a pH is less than 4.0, and a zeta potential of the colloidal silica is −60 mV or higher and −35 mV or lower.

### DETAILED DESCRIPTION

Hereinafter, embodiments of the present invention will be described; however, the present invention is not intended to be limited only to the following embodiments.

Incidentally, unless particularly stated otherwise, regarding operations, the measurement, and the like of physical properties, measurement is made under the conditions of room temperature (20° C. to 25° C.) and a relative humidity of 40% to 50% RH. Furthermore, according to the present specification, the expression “X to Y” representing a range means “X or more and Y or less”.

<Polishing Composition>

A polishing composition according to a mode of the present invention is a polishing composition used for polishing an object to be polished, the polishing composition containing colloidal silica and a quaternary ammonium compound represented by the following Formula (1):

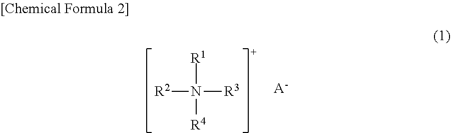

wherein

one or two groups among R¹ to R⁴ each independently represent a first group, which is an alkyl group having 3 or more and 20 or less carbon atoms, an alkenyl group having 3 or more and 20 or less carbon atoms, or an aryl group having 6 to 20 carbon atoms;

the remaining three or two groups other than the first group among R¹ to R⁴ each independently represent a second group, which is an alkyl group having 1 or 2 carbon atoms or an alkenyl group having 2 carbon atoms; and

A⁻ represents a monovalent anion,

wherein the pH is less than 4.0, and the zeta potential of the colloidal silica is −60 mV or higher and −35 mV or lower. According to this polishing composition, SiOC can be polished at a high polishing speed.

The reason why the above-described effect is provided by the polishing composition of the present invention is not necessarily clearly understood; however, the reason is thought to be as follows.

The polishing composition of the present invention contains a colloidal silica having a predetermined zeta potential at a pH of less than 4.0 and a quaternary ammonium compound having a particular structure.

Specifically, the zeta potential of the colloidal silica used for the polishing composition is −60 mV to −35 mV, at a pH of less than 4.0, and the quaternary ammonium compound has one or two hydrophobic groups (first group).

Here, the “zeta (ζ) potential” is an electric potential difference produced at the interface between a solid and a liquid that are in contact with each other when the two perform relative movement. With regard to the polishing composition of the present invention, since the pH is less than 4.0, and there is a quaternary ammonium compound having a particular structure at this pH of less than 4.0, the zeta potential at the SiOC surface is noticeably changed to positive. That is, in the presence of a quaternary ammonium compound having a particular structure at a pH of less than 4.0, the SiOC surface is positively charged, and the absolute value of the zeta potential becomes large.

Therefore, in a case in which SiOC is polished using the polishing composition of the present invention, the colloidal silica is negatively charged, and SiOC is positively charged, in the presence of the quaternary ammonium compound having a particular structure. Thereby, SiOC and the colloidal silica strongly pull against each other, and therefore, the polishing speed for SiOC increases. However, such a mechanism is merely a speculation, and it is unnecessary to say that the mechanism does not limit the technical scope of the present invention.

### [Object to be Polished]

It is preferable that the object to be polished that is polished using the polishing composition of the present invention include SiOC (carbon-containing silicon oxide). That is, the polishing composition of the present invention is used for a use application of polishing an object to be polished including SiOC. The object to be polished may include a material other than SiOC, and the material other than SiOC, which is included in the object to be polished, is not particularly limited, while examples thereof include silicon oxide, silicon nitride, silicon carbonitride (SiCN), polycrystalline silicon (polysilicon), non-crystalline silicon (amorphous silicon), metals, SiGe, and the like.

The object to be polished including SiOC may be an object including SiOC (film) formed by a known method; however, for example, an object to be polished including a SiOC (film) formed by a SOG (Spin on glass) method or a SiOC (film) formed by a flowable chemical vapor deposition (FCVD) method, may be suitably mentioned.

### [Colloidal Silica]

The polishing composition of the present invention includes colloidal silica as abrasive grains. The colloidal silica used for the polishing composition of the present invention exhibits a zeta potential of −60 mV or higher and −35 mV or lower at a pH of less than 4.0. The zeta potential of the colloidal silica is preferably −55 mV or higher and −38 mV or lower, and more preferably −50 mV or higher and −40 mV or lower. As the colloidal silica has a zeta potential in such a range, the polishing speed against SiOC can be further increased.

Here, the zeta potential of the colloidal silica in the polishing composition is calculated by supplying a polishing composition to ELS-Z2 manufactured by Otsuka Electronics Co., Ltd., making measurement by a laser Doppler method (electrophoretic light scattering measurement method) using a flow cell at a measurement temperature of 25° C., and analyzing the obtained data using Smoluchowski's formula.

Examples of a method for producing colloidal silica include a sodium silicate method and a sol-gel method, and any colloidal silica produced by any production method may be suitably used as the colloidal silica of the present invention. However, from the viewpoint of reducing metal impurities, a colloidal silica produced by a sol-gel method is preferred. A colloidal silica produced by a sol-gel method is preferable because the contents of metal impurities having diffusibility in semiconductors and of corrosive ions such as chloride ion are small. The production of colloidal silica according to a sol-gel method can be carried out using a conventionally known technique, and specifically, a colloidal silica can be obtained by using a hydrolyzable silicon compound (for example, an alkoxysilane or a derivative thereof) as a raw material and performing a hydrolysis-condensation reaction.

The type of the colloidal silica that is used is not particularly limited; however, for example, a surface-modified colloidal silica can be used. Surface modification of colloidal silica can be carried out by, for example, chemically bonding a functional group of an organic acid to the surface of the colloidal silica, that is, by immobilization of an organic acid. Alternatively, surface modification of colloidal silica can be carried out by mixing a metal such as aluminum, titanium, or zirconium, or an oxide thereof with colloidal silica and doping the surface of silica particles.

According to a preferred embodiment of the present invention, the colloidal silica that is included in the polishing composition is a colloidal silica having an organic acid immobilized on the surface. A colloidal silica having an organic acid immobilized on the surface have a tendency that the absolute value of the zeta potential in the polishing composition is large compared to ordinary colloidal silica on which an organic acid is not immobilized. Therefore, it is easy to adjust the zeta potential of the colloidal silica in the polishing composition to the range of −60 mV or higher and −35 mV or lower.

Incidentally, the zeta potential of the colloidal silica can be controlled to a desired range by, for example, not only producing a colloidal silica having the above-mentioned organic acid immobilized on the surface but also regulating the type or the amount of addition of the quaternary ammonium compound that will be described below. Furthermore, the zeta potential of the colloidal silica can be controlled to a desired range by, for example, using the acid that will be described below as a pH adjusting agent.

Regarding a colloidal silica having an organic acid immobilized on the surface, colloidal silicas having organic acids such as a carboxylic acid group, a sulfonic acid group, a phosphonic acid group, and an aluminic acid group immobilized on the surface may be preferably used. Among these, from the viewpoint of being easily manufacturable, a colloidal silica having sulfonic acid or a carboxylic acid immobilized on the surface is preferred, and a colloidal silica having sulfonic acid immobilized on the surface is more preferred.

Immobilization of an organic acid to the surface of colloidal silica is not accomplished only by simply causing colloidal silica to co-exist with an organic acid. For example, when sulfonic acid, which is a kind of organic acid, is to be immobilized on colloidal silica, the immobilization can be carried out by, for example, the method described in “Sulfonic acid-functionalized silica through of thiol groups”, Chem. Commun. 246-247 (2003)”. Specifically, a colloidal silica having sulfonic acid immobilized on the surface (sulfonic acid-modified colloidal silica) can be obtained by coupling a silane coupling agent having a thiol group, such as 3-mercaptopropyltrimethoxysilane, with colloidal silica and then oxidizing thiol groups with hydrogen peroxide.

Alternatively, when a carboxylic acid, which is a kind of organic acid, is to be immobilized on colloidal silica, the immobilization can be carried out by, for example, the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000)”. Specifically, a colloidal silica having a carboxylic acid immobilized on the surface (carboxylic acid-modified colloidal silica) can be obtained by coupling a silane coupling agent containing a photoreactive 2-nitrobenzyl ester with colloidal silica and then irradiating the resultant with light.

In the polishing composition of the present invention, the lower limit of the average primary particle size of colloidal silica is preferably 1 nm or more, more preferably 5 nm or more, and even more preferably 7 nm or more. Furthermore, in the polishing composition of the present invention, the upper limit of the average primary particle size of colloidal silica is preferably 100 nm or less, more preferably 75 nm or less, and even more preferably 50 nm or less. When the average primary particle size is in such a range, defects such as scratches that can be generated on the surface of an object to be polished after being polished using the polishing composition can be suppressed. Incidentally, the average primary particle size of colloidal silica is calculated based on, for example, the specific surface area of the colloidal silica measured by the BET method.

In the polishing composition of the present invention, the lower limit of the average secondary particle size of colloidal silica is preferably 2 nm or more, more preferably 10 nm or more, and even more preferably 15 nm or more. Furthermore, in the polishing composition of the present invention, the upper limit of the average secondary particle size of colloidal silica is preferably 200 nm or less, more preferably 150 nm or less, and even more preferably 100 nm or less. When the average primary particle size is in such a range, defects such as scratches that can be generated on the surface of an object to be polished after being polished using the polishing composition can be suppressed. Incidentally, the average secondary particle size of colloidal silica can be measured by, for example, a dynamic light scattering method represented by a laser diffraction scattering method.

The average degree of association of colloidal silica is preferably 5.0 or less, more preferably 3.0 or less, and even more preferably 2.5 or less. As the average degree of association of colloidal silica decreases, a polished surface with fewer surface defects is easily obtained by polishing an object to be polished using the polishing composition. Furthermore, the average degree of association of colloidal silica is preferably 1.0 or higher, and more preferably 1.2 or higher. As the average degree of association of colloidal silica increases, there is an advantage that the rate of removal of the object to be polished by the polishing composition is increased. Incidentally, the average degree of association of colloidal silica is obtained by dividing the value of the average secondary particle size of the colloidal silica by the value of the average primary particle size.

According to the present invention, the shape of the colloidal silica is not particularly limited and may be any of a spherical shape or a non-spherical shape; however, the shape is preferably a non-spherical shape. Specific examples of the non-spherical shape include various shapes such as a polygonal prism shape such as a triangular prism or a quadrangular prism; a cylindrical shape; a straw bag form in which the central portion of a cylinder is inflated compared to edges; a doughnut shape in which the central portion of a disc is penetrated through; a plate shape; a so-called cocoon shape having a constriction at the center; a so-called associated type spherical shape in which a plurality of particles are integrated; a so-called kompeito shape having a plurality of protrusions on the surface; and a rugby ball shape, and there are no particular limitations.

The lower limit of the content of colloidal silica is preferably 0.1% by mass or more, more preferably 0.5% by mass or more, and even more preferably 1% by mass or more, with respect to the polishing composition. Furthermore, the upper limit of the content of colloidal silica is preferably 20% by mass or less, more preferably 10% by mass or less, and even more preferably 5% by mass or less, with respect to the polishing composition. When the content of colloidal silica is in such a range, the polishing speed can be further increased. Incidentally, in a case in which the polishing composition includes two or more kinds of colloidal silicas, the content of colloidal silica means the total amount of these.

When a colloidal silica having the above-described zeta potential in a particular range is included, the polishing composition according to an embodiment of the present invention may include other abrasive grains. Examples of the other abrasive grains include, for example, metal oxide particles such as alumina particles, zirconia particles, and titania particles.

### [Quaternary Ammonium Compound]

The polishing composition of the present invention includes a quaternary ammonium compound represented by the following Formula (1) (hereinafter, also simply referred to as “quaternary ammonium compound”).

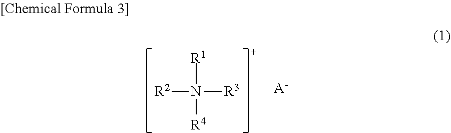

In Formula (1), one or two groups among R¹ to R⁴ each independently represent a first group, which is an alkyl group having 3 or more and 20 or less carbon atoms, an alkenyl group having 3 or more and 20 or less carbon atoms, or an aryl group having 6 or more and 20 or less carbon atoms; and the remaining three or two groups other than the first group among R¹ to R⁴ each independently represent a second group, which is an alkyl group having 1 or 2 carbon atoms or an alkenyl group having 2 carbon atoms.

Here, the first group works as a hydrophobic group for a quaternary ammonium compound. In the polishing composition of the present invention, it is speculated that since a quaternary ammonium compound having a highly hydrophobic first group exists, the quaternary ammonium salt behaves as a cationic surfactant in the polishing composition, and as a result, the zeta potential of SiOC surface can be noticeably changed to positive.

Meanwhile, in a case in which the compound has two of the above-described first group, the first groups may be identical to each other, or may be different from each other. Similarly, second groups that exist as three or two groups may be identical to each other, or may be different from each other.

The alkyl group having 3 or more and 20 or less carbon atoms may be linear or branched. Specific examples of the alkyl group having 3 or more and 20 or less carbon atoms are not particularly limited; however, examples can include an n-propyl group, an isopropyl group, an n-butyl group, an isobutyl group, a sec-butyl group, a tert-butyl group, an n-pentyl group, an isopentyl group, a neopentyl group, a 2-ethylhexyl group, an n-hexyl group, an n-heptyl group, an n-octyl group, an n-nonyl group, an n-decyl group, an n-undecyl group, an n-dodecyl group, an n-tridecyl group, an n-tetradecyl group (myristyl group), an n-pentadecyl group, an n-hexadecyl group (palmityl group), an n-heptadecyl group, an n-octadecyl group (stearyl group), an n-nonadecyl group, an n-icosyl group, and the like.

The alkenyl group having 3 or more and 20 or less carbon atoms may be linear or branched. Specific examples of the alkenyl group having 3 or more and 20 or less carbon atoms are not particularly limited; however, examples can include a 1-propenyl group, an isopropenyl group, a 2-methyl-1-propenyl group, a 1-butenyl group, a 2-butenyl group, a 3-butenyl group, a 2-ethyl-1-butenyl group, a 1-pentenyl group, a 2-pentenyl group, a 3-pentenyl group, a 4-pentenyl group, a 4-methyl-3-pentenyl group, a 1-hexenyl group, a 2-hexenyl group, a 3-hexenyl group, a 4-hexenyl group, a 5-hexenyl group, a 1-octenyl group, a 2-octenyl group, a 1-dodecenyl group, a 2-dodecenyl group, a 3-dodecenyl group, a 2-tetradecenyl group, a 1-hexadecenyl group, a 2-hexadecenyl group, a 1-octadecenyl group, a 2-octadecenyl group, an oleyl group (cis-9-octadecenyl group), and the like.

Examples of the aryl group having 6 or more and 20 or less carbon atoms include a phenyl group, a 2-methylphenyl group, a 3-ethylphenyl group, a naphthyl group, and the like.

Specific examples of the alkyl group having 1 or 2 carbon atoms can include a methyl group, an ethyl group, and the like.

A specific example of the alkenyl group having 2 carbon atoms can be a vinyl group.

With regard to the quaternary ammonium compound represented by Formula (1), the first group (that is, one or two groups among R¹ to R⁴) is preferably an alkyl group having 4 or more and 18 or less carbon atoms, an alkenyl group having 4 or more and 18 or less carbon atoms, or an aryl group having 6 or more and 18 or less carbon atoms; more preferably an alkyl group having 6 or more and 16 or less carbon atoms, an alkenyl group having 6 or more and 16 or less carbon atoms, or an aryl group having 6 or more and 16 or less carbon atoms; even more preferably an alkyl group having 8 or more and 13 or less carbon atoms, an alkenyl group having 8 or more and 13 or less carbon atoms, or an aryl group having 6 or more and 13 or less carbon atoms; and most preferably an alkyl group having 8 or more and 13 or less carbon atoms. Furthermore, the second group (that is, the remaining three or two groups other than the first group among R¹ to R⁴) is preferably a methyl group or an ethyl group, and more preferably a methyl group.

With regard to the quaternary ammonium compound, there are one or two first groups among the four of R¹ to R⁴, and there are three or two second groups among the four of R¹ to R⁴; however, preferably there is one first group, while there are three second groups. Thereby, an increase in the polishing speed is further exhibited.

In Formula (1), A⁻ represents a monovalent anion. The monovalent anion A⁻ is any arbitrary monovalent anion and is not particularly limited; however, halide ions such as fluoride ion, chloride ion, bromide ion, and iodide ion; hydroxide ion; organic acid ions such as benzoate ion; and the like are suitable. Among them, a halide ion is preferred, and chloride ion is more preferred.

Meanwhile, regarding the monovalent anion, one kind thereof may be used singly, or two or more kinds thereof may be used in combination.

Regarding the quaternary ammonium compound represented by Formula (1), in a case in which A⁻ is chloride ion, butyltrimethylammonium chloride, octyltrimethylammonium chloride, dioctyldimethylammonium chloride, decyltrimethyl chloride, dodecyltrimethylammonium chloride, didodecyldimethylammonium chloride, tetradecyltrimethylammonium chloride, hexadecyltrimethylammonium chloride, stearyltrimethylammonium chloride, distearyldimethylammonium chloride, phenyltrimethylammonium chloride, and the like are suitably used. Among these, butyltrimethylammonium chloride, dodecyltrimethylammonium chloride, stearyltrimethylammonium chloride, and phenyltrimethylammonium chloride are preferred; dodecyltrimethylammonium chloride, stearyltrimethylammonium chloride, and phenyltrimethylammonium chloride are more preferred; and dodecyltrimethylammonium chloride and phenyltrimethylammonium chloride are even more preferred.

Regarding these quaternary ammonium compounds, one kind thereof may be used singly, or two or more kinds thereof may be used in combination.

The lower limit of the content of the quaternary ammonium compound is preferably 0.001% by mass or more, more preferably 0.005% by mass or more, and even more preferably 0.01% by mass or more, with respect to the polishing composition. Furthermore, the upper limit of the content of the quaternary ammonium compound is preferably 5% by mass or less, more preferably 1% by mass or less, and even more preferably 0.5% by mass or less, with respect to the polishing composition. When the content is in such a range, the polishing speed can be further increased. Meanwhile, in a case in which the polishing composition includes two or more kinds of quaternary ammonium compounds, the content of the quaternary ammonium compound means the total amount of these.

### [pH and pH Adjusting Agent]

The pH of the polishing composition of the present invention is less than 4.0. If the pH is 4.0 or greater, the polishing speed of the object to be polished cannot be increased. It is desirable that the pH of the polishing composition of the present invention is less than 4.0; however, the pH is more preferably 3.9 or less. When the pH is less than 4.0, there is an advantageous effect that the polishing speed for the object to be polished, particularly SiOC, is increased. The lower limit of the pH is preferably 1.0 or greater, and more preferably 1.5 or greater.

A pH adjusting agent may be used in order to adjust the pH of the polishing composition to a desired value.

Examples of the pH adjusting agent that is used include inorganic acids, organic acids, alkalis, and the like. One kind thereof may be used singly, or two or more kinds thereof may be used in combination.

Specific examples of an inorganic acid that can be used as a pH adjusting agent include, for example, hydrochloric acid, sulfuric acid, nitric acid, hydrofluoric acid, boric acid, carbonic acid, hypophosphorous acid, phosphorous acid, and phosphoric acid. Above all, a preferred inorganic acid is hydrochloric acid, sulfuric acid, nitric acid, or phosphoric acid.

Specific examples of an organic acid that can be used as a pH adjusting agent include, for example, formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, and phenoxyacetic acid. Organic sulfuric acids such as methanesulfonic acid, ethanesulfonic acid, and isethionic acid may also be used. Above all, preferred ones are dicarboxylic acids such as malonic acid, succinic acid, glutaric acid, adipic acid, pimelic acid, maleic acid, phthalic acid, malic acid, and tartaric acid; and tricarboxylic acids such as citric acid.

A salt such as an alkali metal salt of an inorganic acid or an organic acid may also be used as the pH adjusting agent, instead of an inorganic acid or an organic acid, or in combination with an inorganic acid or an organic acid. In the case of a combination of a weak acid and a strong base, a strong acid and a weak base, or a weak acid and a weak base, a pH buffering action can be expected.

Specific examples of an alkali that can be used as a pH adjusting agent include, for example, ammonia, sodium hydroxide, potassium hydroxide, tetramethylammonium hydroxide, and the like. The content of the pH adjusting agent can be selected by appropriately adjusting the content to the extent that provides the effects of the present invention.

Incidentally, the pH of the polishing composition can be measured by, for example, a pH meter.

### [Other Components]

The polishing composition of the present invention may further include, if necessary, other components such as a dispersing medium, an inorganic salt, a surfactant other than the quaternary ammonium compound represented by Formula (1), a water-soluble polymer, an antiseptic agent, an antifungal agent, and an oxidizing agent. Hereinafter, a dispersing medium, an inorganic salt, a surfactant, a water-soluble polymer, an antiseptic agent and an antifungal agent, and an oxidizing agent, which are other components, will be described.

### [Dispersing Medium]

The polishing composition may include a dispersing medium (solvent) for the dispersion of various components that constituent the polishing composition. A dispersing medium has a function of dispersing or dissolving various components. Examples of the dispersing medium include an organic solvent and water; however, it is preferable that the dispersing medium include water, and it is more preferable that the dispersing medium be water.

From the viewpoint of suppressing contamination of the object to be polished and inhibition of the action of other components, the dispersing medium is preferably water that does not contain impurities as far as possible. Regarding such water, for example, water in which the total content of transition metal ions is 100 ppb or less is preferred. Here, the purity of water can be increased by, for example, operations such as removal of impurity ions using an ion exchange resin, removal of foreign matters by a filter, and distillation. Specifically, as the water, for example, it is preferable to use deionized water (ion-exchanged water), pure water, ultrapure water, distilled water, or the like. Usually, it is preferable that 90% by volume or more of the dispersing medium that is included in the polishing composition be water, it is more preferable that 95% by volume or more be water, it is even more preferable that 99% by volume or more be water, and it is particularly preferable that 100% by volume be water.

Furthermore, the dispersing medium may be a mixed solvent of water and an organic solvent for the dispersion or dissolution of various components. In this case, examples of the organic solvent that is used include acetone, acetonitrile, ethanol, methanol, isopropanol, glycerin, ethylene glycol, propylene glycol, and the like, which are organic solvents that are miscible with water. Furthermore, it is also acceptable to disperse or dissolve various components using these organic solvents without mixing with water, and then to mix the resultant with water. These organic solvents can be used singly or in combination of two or more kinds thereof.

### [Inorganic Salt]

The polishing composition of the present invention may also include an inorganic salt. Specific examples of the inorganic salt that is added in the present invention include, for example, ammonium sulfate, magnesium chloride, potassium acetate, aluminum nitrate, and the like.

### [Surfactant]

The polishing composition of the present invention may also include a surfactant other than a quaternary ammonium compound represented by Formula (1). The surfactant that is added in the present invention may be any of an anionic surfactant, a cationic surfactant, an amphoteric surfactant, and a nonionic surfactant.

Examples of the anionic surfactant include, for example, a polyoxyethylene alkyl ether acetic acid, a polyoxyethylene alkyl sulfuric acid ester, an alkyl sulfuric acid ester, a polyoxyethylene alkyl ether sulfuric acid, an alkyl ether sulfuric acid, an alkyl benzenesulfonic acid, an alkyl phosphoric acid ester, a polyoxyethylene alkyl phosphoric acid ester, a polyoxyethylene sulfosuccinic acid, an alkyl sulfosuccinic acid, an alkyl naphthalenesulfonic acid, an alkyl diphenyl ether disulfonic acid, salts of these, and the like.

Regarding examples of the cationic surfactant, any compound other than a quaternary ammonium compound represented by Formula (1) may be used, and examples include a tetramethylammonium salt and the like.

Examples of the amphoteric surfactant include, for example, an alkylbetaine, an alkylamine oxide, and the like.

Examples of the nonionic surfactant include, for example, a polyoxyethylene alkyl ether, a polyoxyalkylene alkyl ether, a sorbitan fatty acid ester, a glycerin fatty acid ester, a polyoxyethylene fatty acid ester, a polyoxyethylene alkylamine, an alkyl alkanolamide, and the like.

The surfactants can be used singly or as mixtures of two or more kinds thereof.

### [Water-Soluble Polymer]

The polishing composition of the present invention may also include a water-soluble polymer. Specific examples of the water-soluble polymer that is added in the present invention include, for example, a polystyrene sulfonate, a polyisoprene sulfonate, a polyacrylate, polymaleic acid, polyitaconic acid, polyvinyl acetate, polyvinyl alcohol, polyglycerin, polyvinylpyrrolidone, a copolymer of isoprenesulfonic acid and acrylic acid, a polyvinylpyrrolidone-polyacrylic acid copolymer, a polyvinylpyrrolidone-vinyl acetate copolymer, a salt of naphthalenesulfonic acid-formalin condensate, a diallylamine hydrochloride-sulfur dioxide copolymer, carboxymethyl cellulose, a salt of carboxymethyl cellulose, hydroxyethyl cellulose, hydroxypropyl cellulose, pullulan, chitosan, and a chitosan salt.

### [Antiseptic Agent and Antifungal Agent]

Examples of the antiseptic agent and the antifungal agent that are used in the present invention include isothiazoline-based antiseptic agents such as 2-methyl-4-isothiazolin-3-one and 5-chloro-2-methyl-4-isothiazolin-3-one, paraoxybenzoic acid esters, phenoxyethanol, and the like. These antiseptic agents and antifungal agents may be used singly or as mixtures of two or more kinds thereof.

### [Oxidizing Agent]

It is preferable that the polishing composition of the present invention include an oxidizing agent. An oxidizing agent has an action of oxidizing the surface of the object to be polished and can further increase the polishing speed for the object to be polished by means of the polishing composition.

Examples of the oxidizing agent include hydrogen peroxide, sodium peroxide, barium peroxide, ozone water, a silver(II) salt, an iron(III) salt, permanganic acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, hypochloric acid, perchloric acid, hydrobromic acid, hydroiodic acid, periodic acid, persulfuric acid, dichloroisocyanuric acid, salts thereof, and the like. These oxidizing agents can be used singly or in combination of two or more kinds thereof. Among these, hydrogen peroxide, ammonium persulfate, periodic acid, hypochloric acid, and sodium dichloroisocyanurate are preferred, and hydrogen peroxide is more preferred.

The lower limit of the content of the oxidizing agent in the polishing composition is preferably 0.001% by mass or more, and more preferably 0.01% by mass or more. By adjusting the lower limit as such, the polishing speed can be further increased. Furthermore, the upper limit of the content of the oxidizing agent in the polishing composition is preferably 30% by mass or less, and more preferably 10% by mass or less. By adjusting the upper limit as such, the material cost for the polishing composition can be suppressed, and in addition, the treatment of the polishing composition after use for polishing, that is, the load of a waste water treatment, can be reduced. Furthermore, the risk of the occurrence of excessive oxidation of the surface of the object to be polished caused by the oxidizing agent can be reduced.

### [Usage Form of Polishing Composition]

The polishing composition of the present invention is typically supplied to an object to be polished in the form of a polishing liquid including the polishing composition, and is used for the polishing of the object to be polished. The polishing composition of the present invention may be, for example, a polishing composition to be diluted (typically, diluted with water) and used as a polishing liquid, or may be a polishing composition to be used directly as a polishing liquid. That is, the concept for the polishing composition according to the technology related to the present invention includes both a polishing composition that is supplied to an object to be polished and used for the polishing of the object to be polished (working slurry), and a concentrated liquid that is diluted and then used for polishing (stock solution of a working slurry). The concentration ratio of the above-described concentrated liquid can be adjusted to, for example, about 2 times to 100 times on a volume basis, and usually, about 5 times to 50 times is adequate.

<Method for Producing Polishing Composition>

The method for producing the polishing composition of the present invention is not particularly limited, and for example, the polishing composition can be obtained by stirring and mixing colloidal silica, a quaternary ammonium compound, and if necessary, other additives such as a pH adjusting agent in a dispersing medium. The details of the various components are as described above. Therefore, the present invention provides a method for producing a polishing composition, the method including mixing colloidal silica and a quaternary ammonium compound represented by the above-described Formula (1), wherein the pH is less than 4.0, and the zeta potential of the colloidal silica is −60 mV or higher and −35 mV or lower.

The temperature at the time of mixing the various components is not particularly limited; however, the temperature is preferably 10° C. or higher and 40° C. or lower, and heating may be performed in order to increase the rate of dissolution. Furthermore, the mixing time is also not particularly limited as long as uniform mixing can be achieved.

<Polishing Method and Method for Producing Semiconductor Substrate>

The present invention provides a polishing method, which includes polishing an object to be polished using the polishing composition of the present invention or a polishing composition produced by the production method of the present invention. Furthermore, the present invention provides a method for producing a semiconductor substrate, the method having the above-described polishing method.

Regarding the polishing apparatus, a general polishing apparatus equipped with a holder that retains a substrate or the like having an object to be polished, a motor with a variable speed of rotation, and the polishing apparatus having a polishing table to which a polishing pad (polishing cloth) can be attached, can be used.

Regarding the polishing pad, a general nonwoven fabric, polyurethane, a porous fluororesin, and the like can be used without any particular limitations. It is preferable that the polishing pad be subjected to groove processing so that the polishing liquid is retained.

Regarding the polishing conditions, for example, the speed of rotation of the polishing table is preferably 10 rpm (0.17 s⁻¹) or more and 500 rpm (8.3 s⁻¹) or less. The pressure (polishing pressure) applied to a substrate having an object to be polished is preferably 0.5 psi (3.4 kPa) or higher and 10 psi (68.9 kPa) or lower. A method of supplying a polishing composition to the polishing pad is also not particularly limited, and for example, a method of continuously supplying the polishing composition by a pump or the like is employed. The supply amount of this is not limited; however, it is preferable that the surface of the polishing pad be always covered with the polishing composition of the present invention.

After completion of polishing, the substrate is washed under flowing water and is dried by shaking off water droplets adhering on the substrate by means of a spin dryer or the like, and thereby a substrate having a layer including a metal is obtained.

The polishing composition of the present invention may be a one-liquid type composition, or may be a multi-liquid type composition including a two-liquid type one.

Embodiments of the present invention have been described in detail; however, these are for explanatory and illustrative purposes and are not restrictive, and it is definitely obvious that the scope of the present invention is to be interpreted based on the attached claims.

The present invention includes the following aspects and modes.

1. A polishing composition, containing colloidal silica and a quaternary ammonium compound represented by the following Formula (1):

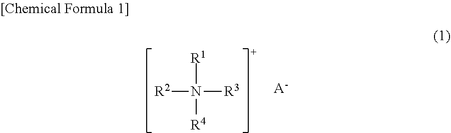

wherein

one or two groups among R¹ to R⁴ each independently represent a first group, which is an alkyl group having 3 or more and 20 or less carbon atoms, an alkenyl group having 3 or more and 20 or less carbon atoms, or an aryl group having 6 or more and 20 or less carbon atoms; the remaining three or two groups other than the first group among R¹ to R⁴ each independently represent a second group, which is an alkyl group having 1 or 2 carbon atoms or an alkenyl group having 2 carbon atoms; and

A⁻ represents a monovalent anion,

wherein a pH is less than 4.0, and

a zeta potential of the colloidal silica is −60 mV or higher and −35 mV or lower.

2. The polishing composition according to the above 1., wherein in the above-described Formula (1), the first group is an alkyl group having 8 or more and 13 or less carbon atoms, an alkenyl group having 8 or more and 13 or less carbon atoms, or an aryl group having 6 or more and 13 or less carbon atoms.

3. The polishing composition according to the above 1. or 2., wherein the colloidal silica is a colloidal silica having an organic acid immobilized on the surface.

4. The polishing composition according to any one of the above 1. to 3., which is used for a use application of polishing an object to be polished including SiOC.

5. The polishing composition according to any one of the above 1. to 4., further including an oxidizing agent.

6. A method for producing a polishing composition, the method including mixing colloidal silica with a quaternary ammonium compound represented by the following Formula (1):

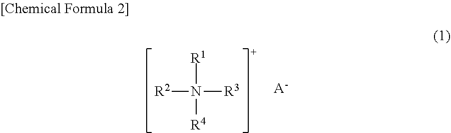

wherein

one or two groups among R¹ to R⁴ each independently represent a first group, which is an alkyl group having 3 or more and 20 or less carbon atoms, an alkenyl group having 3 or more and 20 or less carbon atoms, or an aryl group having 6 or more and 20 or less carbon atoms;

the remaining three or two groups other than the first group among R¹ to R⁴ each independently represent a second group, which is an alkyl group having 1 or 2 carbon atoms or an alkenyl group having 2 carbon atoms; and

A⁻ represents a monovalent anion,

wherein a pH is less than 4.0, and

a zeta potential of the colloidal silica is −60 mV or higher and −35 mV or lower.

7. A polishing method, including polishing an object to be polished using the polishing composition according to any one of the above 1. to 5. or a polishing composition produced by the production method according to the above 6.

8. A method for producing a semiconductor substrate, the method having the polishing method according to the above 7.

### EXAMPLES

The present invention will be described in more detail using the following Examples and Comparative Examples. However, the technical scope of the present invention is not intended to be limited to the following Examples only. Incidentally, unless particularly stated otherwise, the units “%” and “parts” mean “% by mass” and “parts by mass”, respectively. Furthermore, in the following Examples, unless particularly stated otherwise, operations were carried out under the conditions of room temperature (20° C. to 25° C.)/relative humidity of 40% to 50% RH. Meanwhile, the zeta potential of a sulfonic acid-modified colloidal silica or unmodified colloidal silica included in a polishing composition was measured by the following method.

<Measurement of Zeta Potential>

Each of polishing compositions prepared as described below were supplied to ELS-Z2 manufactured by Otsuka Electronics Co., Ltd., and measurement was carried out by a laser Doppler method (electrophoretic light scattering measurement method) using a flow cell at a measurement temperature of 25° C. The data thus obtained were analyzed by Smoluchowski's formula, and thereby the zeta potential of a sulfonic acid-modified colloidal silica or unmodified colloidal silica in the polishing composition was calculated.

<Preparation of Polishing Composition>

(Preparation of Surface-Modified Colloidal Silica)

As colloidal silica, a sulfonic acid-modified colloidal silica having an average primary particle size of 12 nm, an average secondary particle size of 24 nm, and an average degree of association of 2 was prepared by producing the colloidal silica by the method described in “Sulfonic acid—functionalized silica through quantitative oxidation of thiol groups”, Chem. Commun. 246-247 (2003).

Furthermore, a sulfonic acid-modified colloidal silica having an average primary particle size of 35 nm, an average secondary particle size of 70 nm, and an average degree of association of 2 was prepared by a similar method.

Meanwhile, the particle sizes (average primary particle size and average secondary particle size) of abrasive grains in the polishing compositions obtained below were similar to the particle sizes of the abrasive grains used in the respective polishing compositions. That is, in Examples 1 to 7 and Comparative Examples 2 and 3, a polishing composition was produced using either one of the above-described two sulfonic acid-modified colloidal silicas as abrasive grains, and the particle sizes of the sulfonic acid-modified colloidal silica in the polishing composition thus obtained was similar to the particle sizes of the sulfonic acid-modified colloidal silica used.

### Example 1

A mixed liquid was obtained by mixing the individual ingredients and deionized water as a dispersing medium at room temperature (25° C.), so as to adjust the final concentrations of sulfonic acid-modified colloidal silica (average primary particle size 12 nm, average secondary particle size 24 nm, average degree of association 2) obtained above as abrasive grains to 4.0% by mass, and dodecyltrimethylammonium chloride as a quaternary ammonium compound to 0.05% by mass.

Subsequently, maleic acid as a pH adjusting agent was added to the mixed liquid such that the pH would be 2.3, the mixture was stirred and mixed for 30 minutes at room temperature (25° C.), and thus a polishing composition was prepared. The pH of the polishing composition (liquid temperature: 25° C.) was checked using a pH meter (manufactured by HORIBA, Ltd., Model No.: LAQUA). Furthermore, the zeta potential of the sulfonic acid-modified colloidal silica in the polishing composition thus obtained was measured by the above-described method, and the zeta potential was −45 mV. Furthermore, the results of the average primary particle size of the abrasive grains in the polishing composition are presented in Table 1.

### Examples 2, 4, 6, and 7 and Comparative Examples 1 and 3

Polishing compositions of Examples 2, 4, 6, and 7 and Comparative Examples 1 and 3 were prepared in the same manner as in Example 1, except that the type of the abrasive grains and the type of the quaternary ammonium compound were changed as shown in Table 1. Meanwhile, when an agent is indicated with the symbol “-” in the following Table 1, it is implied that the agent is not included. The pH of the polishing compositions thus obtained, and the average primary particle size and zeta potential of the sulfonic acid-modified colloidal silica or unmodified colloidal silica in the polishing compositions are presented in the following Table 1.

### Example 3 and Comparative Example 2

Polishing compositions of Example 3 and Comparative Example 2 were prepared in the same manner as in Example 1, except that the content of the pH adjusting agent was changed so as to obtain the pH described in Table 1. Incidentally, in Example 3, maleic acid was added as a pH adjusting agent such that the pH of the polishing composition would be 3.8, and in Comparative Example 2, maleic acid was added as a pH adjusting agent such that the pH of the polishing composition would be 6.0. The pH of the polishing composition thus obtained, and the average primary particle size and zeta potential of the sulfonic acid-modified colloidal silica in the polishing composition are presented in the following Table 1.

### Example 5

A polishing composition was prepared in the same manner as in Example 1, except that hydrogen peroxide as an oxidizing agent was added so as to obtain a final concentration of 1% by mass, in addition to the sulfonic acid-modified colloidal silica and the quaternary ammonium compound. The pH of the polishing composition thus obtained, and the average primary particle size and zeta potential of the sulfonic acid-modified colloidal silica in the polishing composition are presented in the following Table 1.

### [Measurement of Average Primary Particle Size]

The average primary particle size of abrasive grains was calculated from the specific surface area of the abrasive grains according to the BET method measured using “Flow SorbII 2300” manufactured by Micromeritics Instrument Corporation and the density of the abrasive grains.

### [Evaluation of Average Secondary Particle Size]

The average secondary particle size of colloidal silica in the polishing composition was measured according to a light scattering method using laser light, and as the measuring instrument, a dynamic light scattering type particle size distribution meter, UPA-UT151, manufactured by NIKKISO CO., LTD. was used.

### [Evaluation of Polishing Speed]

As objects to be polished, a silicon wafer (300 mm, blanket wafer) having a SiOC film having a thickness of 450 Å formed on the surface by an FCVD (Flowable CVD) method and a silicon wafer (300 mm, blanket wafer) having a SiOC film having a thickness of 5000 Å formed on the surface by a SOG (Spin on glass) method were prepared. Coupons obtained by cutting each of the wafers as objects to be polished into chips having a size of 30 mm×30 mm were used as specimens, and each of the objects to be polished was polished under the following conditions for polishing using each of the polishing compositions obtained as described above. Meanwhile, 1 Å is equal to 0.1 nm.

(Conditions for Polishing)

EJ-380IN-CH (manufactured by Engis Japan Corporation) was used as a polishing machine, and a hard polyurethane pad, IC1010 (manufactured by Rohm and Haas Company) was used as a polishing pad. Polishing was performed under the conditions of a polishing pressure of 3.8 psi (21.0 kPa), a speed of table rotation of 60 rpm, a speed of carrier rotation of 60 rpm, and a supply rate of the polishing composition of 100 ml/min, for a polishing time of 60 seconds.

(Polishing Speed)

The polishing speed (Removal Rate: RR) was calculated by the following formula.

$$[ Mathematical Formula 1 ]$$

$$Polishing speed [ Å \text{/} min ] = \frac{\begin{matrix}Film thickness before polishing [ Å ] - \\ Film thickness after polishing [ Å ]\end{matrix}}{Polishing time [ min ]}$$

The film thickness was determined using a light interference type film thickness measurement apparatus (manufactured by Dainippon Screen Manufacturing Co., Ltd., Model No.: LAMBDA ACE VM-2030), and the polishing speed was evaluated by dividing the film thickness difference obtained before and after polishing, by the polishing time.

The evaluation results for the polishing speed are presented in the following Table 1.

TABLE 1

| | | | | | | | Other | | | | |
|---|---|---|---|---|---|---|---|---|---|---|---|
| | | | | | | | component | | | | |
| | | | | | | | (oxidizing | | | SiOC | |
| | Abrasive grains | | | | | | agent or the | | | polishing | |
| | | Average | | | Quaternary ammonium compound | | like) | | | speed | |
| | | primary | Zeta | Content | | Content | | Content | | SiOC | SiOC |
| | | particle | potential | (% by | | (% by | | (% by | | by | by |
| | Type | size | (mV) | mass) | Type | mass) | Type | mass) | pH | FCVD | SOG |
| Example 1 | Sulfonic acid- | 12 nm | −45 | 4 | Dodecyltrimethylammonium | 0.05 | — | − | 2.3 | 28 | 300 |
| | modified | | | | chloride | | | | | | |
| | colloidal | | | | | | | | | | |
| | silica | | | | | | | | | | |
| Example 2 | Sulfonic acid- | 35 nm | −48 | 4 | Dodecyltrimethylammonium | 0.05 | − | − | 2.3 | 33 | 330 |
| | modified | | | | chloride | | | | | | |
| | colloidal | | | | | | | | | | |
| | silica | | | | | | | | | | |
| Comparative | Unmodified | 35 nm | 0 | 4 | Dodecyltrimethylammonium | 0.05 | − | − | 2.3 | 8 | 80 |
| Example 1 | colloidal | | | | chloride | | | | | | |
| | silica | | | | | | | | | | |
| Example 3 | Sulfonic acid- | 12 nm | −45 | 4 | Dodecyltrimethylammonium | 0.05 | − | − | 3.8 | 28 | 300 |
| | modified | | | | chloride | | | | | | |
| | colloidal | | | | | | | | | | |
| | silica | | | | | | | | | | |
| Comparative | Sulfonic acid- | 12 nm | −45 | 4 | Dodecyltrimethylammonium | 0.05 | − | − | 6.0 | 16 | 170 |
| Example 2 | modified | | | | chloride | | | | | | |
| | colloidal | | | | | | | | | | |
| | silica | | | | | | | | | | |
| Example 4 | Sulfonic acid- | 12 nm | −45 | 4 | Butyltrimethylammonium | 0.05 | − | − | 2.3 | 22 | 220 |
| | modified | | | | chloride | | | | | | |
| | colloidal | | | | | | | | | | |
| | silica | | | | | | | | | | |
| Example 5 | Sulfonic acid- | 12 nm | −45 | 4 | Dodecyltrimethylammonium | 0.05 | H₂O₂ | 1 | 2.3 | 35 | 380 |
| | modified | | | | chloride | | | | | | |
| | colloidal | | | | | | | | | | |
| | silica | | | | | | | | | | |
| Comparative | Sulfonic acid- | 12 nm | −45 | 4 | Tetramethylammonium | 0.05 | − | − | 2.3 | 12 | 130 |
| Example 3 | modified | | | | hydroxide | | | | | | |
| | colloidal | | | | | | | | | | |
| | silica | | | | | | | | | | |
| Example 6 | Sulfonic acid- | 12 nm | −45 | 4 | Stearyltrimethylammonium | 0.05 | − | − | 2.3 | 23 | 240 |
| | modified | | | | chloride | | | | | | |
| | colloidal | | | | | | | | | | |
| | silica | | | | | | | | | | |
| Example 7 | Sulfonic acid- | 12 nm | −45 | 4 | Phenyltrimethylammonium | 0.05 | − | − | 2.3 | 26 | 280 |
| | modified | | | | chloride | | | | | | |
| | colloidal | | | | | | | | | | |
| | silica | | | | | | | | | | |

As shown in Table 1, in a case in which the polishing compositions of Examples 1 to 7 were used, the polishing speed was more than 20 nm/min, and it was found that SiOC can be polished at a high polishing speed compared to the polishing compositions of Comparative Examples 1 to 3.

Through a comparison of Example 1 with Comparative Example 2, it is understood that when the pH is not less than 4.0, even in a case in which the zeta potential of the colloidal silica is in a predetermined range in the presence of a quaternary ammonium compound having a hydrophobic first group, the polishing speed is obviously decreased. Furthermore, when Example 1 is compared with Comparative Example 3, it is understood that in a case in which the quaternary ammonium compound included in the polishing composition does not have a hydrophobic first group, the polishing speed is noticeably decreased.

From this, it is understood that at a pH of less than 4.0, when the zeta potential of the colloidal silica is in a predetermined range in the presence of a quaternary ammonium compound having a hydrophobic first group, the polishing speed for SiOC is increased.

Furthermore, it is understood that in the case of using the polishing composition of Example 5 including hydrogen peroxide, which is an oxidizing agent, the polishing speed for SiOC is further increased.

The present application is based on Japanese Patent Application No. 2019-167314, filed on Sep. 13, 2019, the disclosure of which is incorporated herein by reference in its entirety.

1. A polishing composition, containing colloidal silica and a quaternary ammonium compound represented by the following Formula (1): 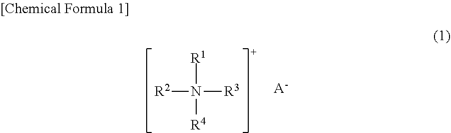
wherein
one or two groups among R1 to R4 each independently represent a first group, which is an alkyl group having 3 or more and 20 or less carbon atoms, an alkenyl group having 3 or more and 20 or less carbon atoms, or an aryl group having 6 or more and 20 or less carbon atoms;
the remaining three or two groups other than the first group among R1 to R4 each independently represent a second group, which is an alkyl group having 1 or 2 carbon atoms or an alkenyl group having 2 carbon atoms; and
A⁻ represents a monovalent anion,
wherein a pH is less than 4.0, and
a zeta potential of the colloidal silica is −60 mV or higher and −35 mV or lower.

2. The polishing composition according to claim 1, wherein in the above-described Formula (1), the first group is an alkyl group having 8 or more and 13 or less carbon atoms, an alkenyl group having 8 or more and 13 or less carbon atoms, or an aryl group having 6 or more and 13 or less carbon atoms.

3. The polishing composition according to claim 1, wherein the colloidal silica is a colloidal silica having an organic acid immobilized on the surface.

4. The polishing composition according to claim 1, which is used for a use application of polishing an object to be polished including SiOC.

5. The polishing composition according to claim 1, further including an oxidizing agent.

6. A method for producing a polishing composition, the method including mixing colloidal silica with a quaternary ammonium compound represented by the following Formula (1): 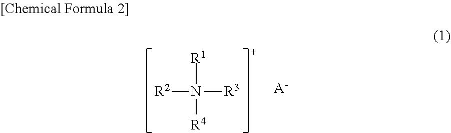
wherein
one or two groups among R1 to R4 each independently represent a first group, which is an alkyl group having 3 or more and 20 or less carbon atoms, an alkenyl group having 3 or more and 20 or less carbon atoms, or an aryl group having 6 or more and 20 or less carbon atoms;
the remaining three or two groups other than the first group among R1 to R4 each independently represent a second group, which is an alkyl group having 1 or 2 carbon atoms or an alkenyl group having 2 carbon atoms; and
A⁻ represents a monovalent anion,
wherein a pH is less than 4.0, and
a zeta potential of the colloidal silica is −60 mV or higher and −35 mV or lower.

7. A polishing method, including polishing an object to be polished using the polishing composition according to claim 1.

8. A method for producing a semiconductor substrate, including polishing an object to be polished using the polishing composition according to claim 1.
